(19) United States
(12) Patent Application Publication
(10) Pub. No.: US 2010/0021788 A1
(43) Pub. Date: Jan. 28, 2010

(54) POLYMER ELECTROLYTE COMPOSITE FILM, MEMBRANE-ELECTRODE ASSEMBLY AND FUEL CELL

(75) Inventors: Mamiko Kumagai, Tokyo (JP); Kenji Yamada, Yokohama-shi (JP); Kazuhiro Yamauchi, Suntou-gun (JP); Kyoko Kumagai, Toyota-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/518,190

(22) PCT Filed: May 15, 2008
(86) PCT No.: PCT/JP2008/059394

§ 371 Date: Jun. 8, 2009

(30) Foreign Application Priority Data
May 17, 2007 (JP) 2007-131988

(51) Int. Cl. H01M 8/10; C23C 14/32

(52) U.S. Cl. 429/30; 204/192.1

(57) ABSTRACT

The invention provides a polymer electrolyte composite film which is superior in membrane properties and membrane strength and can achieve high proton conductivity, and a membrane-electrode assembly and a fuel cell which use the membrane. The polymer electrolyte composite film contains a block copolymer including a hydrophilic block and a hydrophobic block, and a solid acid, and has a microphase separation structure including a hydrophilic domain formed from the hydrophilic block and a hydrophobic domain formed from the hydrophobic block. The solid acid is localized in the hydrophilic domain.

### TECHNICAL FIELD

This invention relates to a polymer electrolyte composite film containing a block copolymer and a solid acid, and a membrane-electrode assembly and a fuel cell which use the same.

### BACKGROUND ART

Polymer electrolyte fuel cells (PEFCs) have advantages in that they can easily be operated at relatively low temperature, have such a simple cell structure as to facilitate maintenance and can be made small-sized and light-weight. Accordingly, they are attracting attention particularly as portable power sources. As a polymer electrolyte membrane which is presently most widely used as an electrolyte membrane for PEFCs, NAFION (registered trademark; a product of DuPont) may be cited. The NAFION (registered trademark) membrane shows high proton conductivity and good chemical stability and mechanical strength. It, however, requires water to maintain ion conductivity, and hence has a disadvantage such that it has very low ion conductivity when the membrane is lacking in water, e.g., when it is in a state of high temperature or in an initial state of power generation. Accordingly, the development of an electrolyte membrane is sought which has good proton conductivity even when it is left under low relative humidity, e.g., when it is kept at a high temperature or when power generation is started.

As a measure therefor, i.e., as a method by which the electrolyte membrane can be improved in proton conductivity even when being left under low relative humidity, one is available in which a solid acid having water retention properties and proton conductivity is added to an existing polymer.

For example, in J. Membrane Sci. 232 (2004), pp. 31-44 (Non-patent Document 1), a polymer electrolyte membrane is proposed in which a heteropolyacid is added to the NAFION (registered trademark) membrane, and states that cell properties in a high temperature and low humidity environment are improved.

In National Publication No. 2004-509224 (Patent Document 1), a polymer electrolyte membrane is proposed in which a heteropolyacid is added to a sulfonated polymer of an aromatic high molecular compound such as polysulfone or a polyimide. It is stated therein that such a membrane can retain good proton conductivity even in an environment of low relative humidity because the heteropolyacid is present in an ionic hydrophilic region of a microphase separation structure formed from a matrix polymer.

However, in Non-patent Document 1, the heteropolyacid agglomerates in the membrane in the order of several microns, and hence membrane strength is greatly lowered.

In Patent Document 1, it is disclosed that the heteropolyacid is present in an agglomerate state in the ionic hydrophilic region included in the microphase separation structure, but any data such as SEM images clearly showing such a fact are not disclosed. Thus, it is presumed difficult to allow the heteropolyacid to be present in the ionic hydrophilic region of the microphase separation structure disclosed in Patent Document 1. This is because, in general, aromatic polymer membranes composed of random copolymers do not show any clear microphase separation structure to make it difficult to control the phase separated structure. In addition, it is considered difficult to quantitatively evaluate the correlation between the uniform distribution of the solid acid and membrane structure, and also difficult to control factors that may influence the ion conductivity, such as domain size, periodicity and domain continuity.

### DISCLOSURE OF THE INVENTION

The present invention has been made taking into account the above technical background, and provides a polymer electrolyte composite film exhibiting high proton conductivity in an environment of low relative humidity and having a high membrane strength, and a membrane-electrode assembly and a fuel cell which use such a polymer electrolyte composite film.

The polymer electrolyte composite film that can resolve the above problems is a polymer electrolyte composite film which contains a block copolymer including a hydrophilic block and a hydrophobic block, and a solid acid, wherein

the polymer electrolyte composite film has a microphase separation structure including

a hydrophilic domain formed from the hydrophilic block, and

a hydrophobic domain formed from the hydrophobic block, and

the solid acid is localized in the hydrophilic domain.

It is preferable that the hydrophilic block includes an ion conductive component, and the hydrophobic block includes a non-ion conductive component.

It is preferable that the microphase separation structure is a structure in which a continuous phase including the hydrophilic domain is present in a matrix including the hydrophobic domain.

The solid acid is preferably a heteropolyacid.

The membrane-electrode assembly of the present invention is a membrane-electrode assembly having the above polymer electrolyte composite film.

The fuel cell of the present invention is a fuel cell having the above polymer electrolyte composite film.

According to the present invention, the solid acid is localized in an ion conductive domain of the microphase separation structure formed from the block copolymer, whereby a polymer electrolyte composite film can be provided which is superior in membrane properties (a uniform membrane free of any agglomeration or precipitation of the solid acid), and has high membrane strength and high proton conductivity in an environment of low relative humidity.

The present invention can also provide a membrane-electrode assembly and a fuel cell which use such a polymer electrolyte composite film.

Further features of the present invention will become apparent from the following description of exemplary embodiments with reference to the attached drawings.

### BRIEF DESCRIPTION OF THE DRAWINGS

FIG. 1 is a diagrammatic view showing an example of the polymer electrolyte composite film of the present invention.

FIG. 2 is a transmission electron microscope (TEM) photograph of a polymer electrolyte composite film composed of a block copolymer and phosphotungstic acid according to Example 1.

FIG. 3 is a transmission electron microscope (TEM) photograph of a polymer electrolyte composite film composed of a block copolymer and phosphotungstic acid according to Example 2.

FIG. 4 is a transmission electron microscope (TEM) photograph of a polymer electrolyte composite film composed of a random copolymer and phosphotungstic acid according to Comparative Example 1.

### BEST MODE FOR CARRYING OUT THE INVENTION

The present invention is described below in detail.

The present invention is directed to a polymer electrolyte composite film which contains a block copolymer including a hydrophilic block and a hydrophobic block, and a solid acid, wherein

the polymer electrolyte composite film has a microphase separation structure including

a hydrophilic domain formed from the hydrophilic block, and

a hydrophobic domain formed from the hydrophobic block, and

the solid acid is localized in the hydrophilic domain.

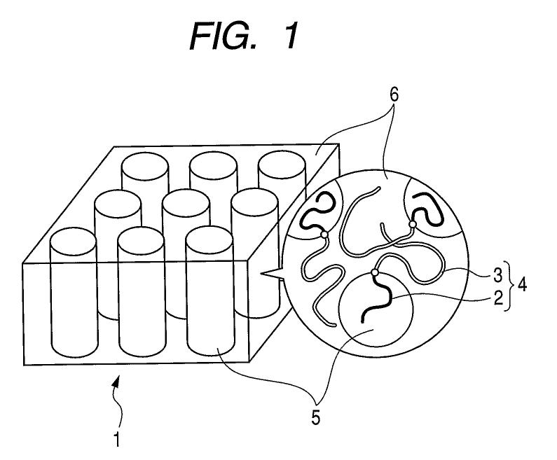

An example of the polymer electrolyte composite film of the present invention is shown in FIG. 1.

A polymer electrolyte composite film 1 contains a block copolymer 4 and a solid acid. A microphase separation structure formed from the block copolymer 4 is made up of a hydrophilic domain 5 formed from a hydrophilic block 2 included in the block copolymer 4 and a hydrophobic domain 6 formed from a hydrophobic block 3 included in block the block copolymer 4.

The microphase separation structure of the polymer electrolyte composite film is a structure made up of aggregates (domains) of about 100 nanometers to about 50 micrometers in size, formed by self-assembly of each of hydrophilic block 2 and hydrophobic block 3 included in the block copolymer 4.

In FIG. 1, a cylindrical structure is given as an example of the microphase separation structure. The microphase separation structure may be any structure such as a spherical structure, a cylindrical structure, and a lamellar structure, depending on the compositional ratio and compatibility of the respective blocks. In particular, from the viewpoint of water stability and membrane strength, a structure is commonly preferred in which hydrophilic domains are phase-separated in the shape of cylinders or spheres in a hydrophobic matrix. On the other hand, from the viewpoint of the continuity of proton conductive paths, a structure is preferable in which hydrophilic domains are connected in the shape of cylinders or lamellas in a hydrophobic matrix. Accordingly, from both of the above viewpoints, the microphase separation structure is preferably a structure in which hydrophilic domains are phase-separated in the shape of cylinders in a hydrophobic matrix. Herein, “the hydrophobic domain is a matrix” refers to a structure in which the hydrophobic domain surrounds hydrophilic domains in the microphase separation structure.

The block copolymer 4 is made up of the hydrophilic block 2 and the hydrophobic block 3.

The block copolymer 4 preferably has a structure having no aromatic group in the backbone chain. This is because, in a structure having any aromatic group in the backbone chain, the phase separation structure is not made clear on account of the bulkiness of the backbone chain to make it difficult to introduce a large quantity of solid acid, and because an aromatic polymer has so high a glass transition point (Tg) as to make it difficult to control the above phase separation structure.

The structure having no aromatic group in the backbone refers to a concept that the backbone chain is composed of an aliphatic hydrocarbon and includes an aliphatic hydrocarbon the constituent atom or atoms of which has or have been substituted with an atom or a group of atoms other than the aromatic group.

The polymer making up the hydrophilic block 2 is a polymer having an affinity for water, and includes, e.g., polymers having a hydroxyl group, a carboxylic group, an amine group or an amide group. More specifically, it includes polymers synthesized from monomers such as acrylic acid, methacrylic acid, vinyl alcohol, ethylene oxide, propylene oxide, ethylene glycol, acrylamide and vinyl pyrrolidone. However, it has only to be a substance which has an affinity for water and with which the block copolymer can be synthesized, and examples are by no means limited to the above.

Further, the polymer making up the hydrophilic block 2 preferably has an ion exchange group. In other words, it is preferable for the hydrophilic block 2 to be composed of an ion conductive component. As having the ion exchange group, proton conductors can be contained in a larger amount in the whole polymer electrolyte composite film, to thereby improve in the proton conductivity. The amount of the ion exchange group is not particularly limited as long as a membrane obtained when being formed by usual solvent casting does not come water-soluble.

The polymer having such an ion exchange group (i.e., an ion conductive polymer) has only to be a polymer with which the block copolymer can be synthesized, and there is no particular limitation also on the ion exchange group contained therein, which can arbitrarily be selected according to purposes. For example, a sulfonic acid, a carboxylic acid, phosphoric acid, phosphonic acid, phosphonous acid or the like may particularly preferably be used. One or two or more ion exchange groups may be contained in the polymer.

Examples of the chemical structures of repeating units making up the ion conductive polymer include, but are not limited to, sulfonic acid (or sulfonate) group-containing styrene, sulfonic acid (or sulfonate) group-containing acrylate (or methacrylate), sulfonic acid (or sulfonate) group-containing acrylamide (or methacrylamide), sulfonic acid (or sulfonate) group-containing butadiene, sulfonic acid (or sulfonate) group-containing isoprene, sulfonic acid (or sulfonate) group-containing ethylene, and sulfonic acid (or sulfonate) group-containing propylene. Further, in order to improve the strength of the electrolyte membrane, to enhance dimensional stability and to make the phase separation structure clear, it is possible to use compounds in which fluorine is introduced into the above chemical structures, such as perfluorocarbon sulfonic acid, perfluorocarbon phosphonic acid, and trifluorostyrene sulfonic acid.

There are no particular limitations on how to synthesize the block copolymer having such an ion exchange group. In this case, a monomer having the ion exchange group at the stage of a monomer may be polymerized to synthesize the block copolymer, or the ion exchange group may be introduced after the block copolymer has been synthesized.

The hydrophobic block 3 is composed of a hydrophobic polymer, in other words, a hydrophobic component.

The hydrophobic polymer may be any hydrophobic polymer as long as it is a polymer having no hydrophilic group, can synthesize the block copolymer and can form a membrane structure. For example, it includes polymers synthesized from monomers such as acrylic acid esters, methacrylic acid esters, styrene derivatives, conjugated dienes and vinyl esterified compounds. Besides these, the monomer capable of forming the hydrophobic polymer includes, but is not limited to:

styrene, and α-, o-, m- or p-alkyl, alkoxyl, halogen, haloalkyl, nitro, cyano, amide or ester substituted products of styrene;

polymerizable unsaturated aromatic compounds such as 2,4-dimethylstyrene, paradimethylaminostyrene, vinylbenzyl chloride, vinyl benzaldehyde, indene, 1-methylindene, acenaphthalene, vinylnaphthalene, vinylanthracene, vinylcarbazole, 2-vinylpyridine, 4-vinylpyridine and 2-vinylfluorene;

alkyl acrylates (or methacrylates) such as methyl acrylate (or methacrylate), ethyl acrylate (or methacrylate), n-propyl acrylate, n-butyl acrylate, 2-ethylhexyl acrylate (or methacrylate) and stearyl acrylate (or methacrylate);

unsaturated monocarboxylates such as methyl crotonate, ethyl crotonate, methyl cinnamate and ethyl cinnamate; fluoroalkyl acrylates (or methacrylates) such as trifluoroethyl acrylate (or methacrylate), pentafluoropropyl acrylate (or methacrylate) and heptafluorobutyl acrylate (or methacrylate);

siloxanyl compounds such as trimethylsiloxanyl dimethylsilylpropyl acrylate (or methacrylate), tris(trimethylsiloxanyl)silylpropyl acrylate (or methacrylate), and diacryloyl(or dimethacryloyl)propyl dimethylsilyl ether;

hydroxyalkyl acrylates (or methacrylates) such as 2-hydroxyethyl acrylate (or methacrylate), 2-hydroxypropyl acrylate (or methacrylate) and 3-hydroxypropyl acrylate (or methacrylate); amine-containing acrylates (or methacrylates) such as dimethylaminoethyl acrylate (or methacrylate), diethylaminoethyl acrylate (or methacrylate) and t-butylaminoethyl acrylate (or methacrylate);

hydroxyalkyl esters of unsaturated carboxylic acids, such as 2-hydroxyethyl crotonate, 2-hydroxypropyl crotonate and 2-hydroxypropyl cinnamate; unsaturated alcohols such as allyl (or methallyl) alcohol;

unsaturated carboxylic (or monocarboxylic) acids such as acrylic (or methacrylic) acid, crotonic acid and cinnamic acid; epoxy group-containing acrylates (or methacrylates) such as glycidyl acrylate (or methacrylate), glycidyl α-ethyl acrylate, glycidyl α-n-propyl acrylate, glycidyl α-n-butyl acrylate, 3,4-epoxybutyl acrylate (or methacrylate), 6,7-epoxyheptyl acrylate (or methacrylate), 6,7-epoxyheptyl a-ethyl acrylate, o-vinylbenzyl glycidyl ether, m-vinylbenzyl glycidyl ether, p-vinylbenzyl glycidyl ether, β-methylglycidyl acrylate (or methacrylate), β-ethylglycidyl acrylate (or methacrylate), β-propylglycidyl acrylate (or methacrylate), β-methylglycidyl α-ethyl acrylate, 3-methyl-3,4-epoxybutyl acrylate (or methacrylate), 3-ethyl-3,4-epoxybutyl acrylate (or methacrylate), 4-methyl-4,5-epoxypentyl acrylate (or methacrylate), 5-methyl-5,6-epoxyhexyl acrylate (or methacrylate) and 3-methyl-3,4-epoxybutyl acrylate (or methacrylate); and mono- or di-esters of these;

maleimides such as N-methylmaleimide, N-butylmaleimide, N-phenylmaleimide, N-o-methylphenylmaleimide, N-m-methylphenylmaleimide, N-p-methylphenylmaleimide, N-o-hydroxyphenylmaleimide, N-m-hydroxyphenylmaleimide, N-p-hydroxyphenylmaleimide, N-methoxyphenylmaleimide, N-m-methoxyphenylmaleimide, N-p-methoxyphenylmaleimide, N-o-chlorophenylmaleimide, N-m-chlorophenylmaleimide, N-p-chlorophenylmaleimide, N-o-carboxyphenylmaleimide, N-p-carboxyphenylmaleimide, N-p-nitrophenylmaleimide, N-ethylmaleimide, N-cyclohexylmaleimide and N-isopropylmaleimide, acrylo (or methacrylo)nitrile, and vinyl chloride.

The method of synthesizing the block copolymer is not particularly limited as long as it can produce the block copolymer. For example, the block copolymer may be obtained by successive block polymerization using living polymerization, or by allowing a prepolymer of the hydrophobic block to react with a prepolymer of the hydrophilic block. Either may arbitrarily be selected according to purposes.

There are no particular limitations on the molecular weight of the block copolymer as long as the block copolymer forms the microphase separation structure.

There are no particular limitations on the compositional ratio of the block copolymer as long as the block copolymer forms the microphase separation structure. In the case where the structure is obtained in which hydrophilic domains are phase-separated in the shape of cylinders in a hydrophobic matrix, the hydrophilic domains may preferably be in a volume fraction of from 5% or more and 40% or less. However, since the microphase separation structure used in the present invention is a structure in which the solid acid is incorporated in the hydrophilic moiety, the hydrophilic domains may be in a volume fraction outside the above range, depending on the block copolymer to be used and the amount of the solid acid to be incorporated. The size of each domain may be controlled by the chain length or chemical structure of the block copolymer and the compositional ratio of the hydrophobic block to the hydrophilic block.

The volume fraction herein referred to indicates the volume fraction value of each of the block chains making up the block copolymer, with respect to one molecular chain of the block copolymer. The volume fraction of each block may be determined by the molecular weight and specific gravity of each block.

Specifically, in a block copolymer made up of a hydrophobic block A and a hydrophilic block B, the volume fraction of the hydrophilic block B can be calculated according to the following expression.

Volume fraction (%)=(B/b)/{(A/a+B/b)}×100.

The molecular weight of the hydrophobic block included in a block polymer is represented by A (g/mol), the specific gravity of the hydrophobic block is represented by a (g/cm³), the molecular weight of the hydrophilic block included in the block polymer is represented by B (g/mol), and the specific gravity of the hydrophilic block is represented by b (g/cm³).

The solid acid is a Brønsted acid, and commonly has a hydrophilic nature (has very high affinity for hydrophilic groups). Hence, when the solid acid is introduced into the polymer electrolyte composite film having the microphase separation structure including a hydrophilic domain and a hydrophobic domain, it is predominantly introduced into the hydrophilic domain and is structurally localized. The solid acid has high proton conductivity and water retention in itself, and hence the hydrophilic domain where the solid acid is localized exhibits a high proton conductivity. On the other hand, the hydrophilic moiety into which almost no solid acid is introduced has the function of keeping as a matrix the shape of the polymer electrolyte composite film. Thus, when the solid acid is localized in the hydrophilic domain, the polymer electrolyte composite film is allowed to have high proton conductivity and good membrane strength.

Herein, the wording “the solid acid is localized in the hydrophilic domain (as compared with the hydrophobic domain)” refers to a state that agglomerates of the solid acid which are in the order of several μm are not observed in the composite polymer electrolyte and also the solid acid has been introduced into the hydrophilic domain in a larger quantity than into the hydrophobic domain. The presence or absence of localization of the solid acid can be ascertained by observing the resultant electrolytic membrane with a transmission electron microscope (TEM).

In order to achieve such localization into the hydrophilic domain, the solid acid introduced into the membrane is preferably in an amount of from 5% or more and 400% or less based on the weight of the hydrophilic block in the block copolymer. If the amount is less than 5%, the effects on proton conductivity and water retention are not obtainable in some cases. If the amount is more than 400%, the solid acid may be precipitated and agglomerated in the block copolymer to disrupt the phase separation structure of the block copolymer or cause macrophase separation, and hence inhibit a flexible membrane from being formed.

Examples of such a solid acid include heteropolyacids of various types, silicon oxide, zirconium phosphate, zirconium sulfate, titanium oxide, and cesium salts such as CsHSO₄, CsH₂SO₄ and Cs₂(HSO₄)(H₂SO₄). The heteropolyacid is formed from, as a basic unit, a polygon such as a tetrahedron, a quadrangular pyramid or an octahedron, formed by coordination of four to six oxide ions with transition metal ions such as vanadium(V), molybdenum(VI) and tungsten(VI). Specifically, the heteropolyacid includes phosphotungstic acid, silicotungustic acid and phosphomolybdic acid. Any of these may be used alone or in a combination of two or more types, or may be incorporated with at least one phosphoric acid compound selected from the group consisting of phosphoric acid, phosphorous acid, and derivatives thereof.

A method for producing the polymer electrolyte composite film of the present invention is described below.

Examples of the method of producing the polymer electrolyte composite film of the present invention include the following:

(1) a method in which the solid acid is introduced in the step of producing a polymer electrolyte membrane; and

(2) a method in which the solid acid is introduced after the membrane has been produced.

The method (1) specifically include a method in which the solid acid and the block copolymer are dissolved in an organic solvent or the like to prepare a solution, and thereafter the solution is applied onto the surface of a substrate by coating or the like, followed by evaporation of the solvent to produce a membrane. The employment of the method (1) is preferred because the solid acid can be introduced in a large quantity. Here, coating means such as spin coating, dipping, roll coating, spraying or casting may be used as a method for coating the substrate surface.

There are no particular limitations on the organic solvent (for preparing a polymer solution) used in producing the membrane as long as the block copolymer and the solid acid can uniformly be dissolved therein and the microphase separation structure is obtainable.

The composite polymer membrane thus obtained assumes a non-equilibrium microphase separation structure. Accordingly, the membrane thus produced is subjected to heat treatment enough to bring the non-equilibrium microphase separation structure into an equilibrium state, whereupon it is transformed into a highly orderly microphase separation structure such as a spherical structure, a cylindrical structure, a co-continuous structure, a lamellar structure, etc., as disclosed in Bates, F. S.; Fredrickson, G. H.; Annu. Res. Phys. Chem. 1990 (41) 525. Such heat treatment may be carried out to transform the microphase separation structure to be in an equilibrium state. Where the microphase separation structure in a non-equilibrium state is intended to be maintained, either of the components may be cross-linked so as to control the movement of molecular chains to prevent the structure from being transformed. Alternatively, in the step of evaporating the solvent, an external field may further be applied so as to bring the microphase separation structure into a structure in which the phases are arranged in a certain direction. In the present invention, the “external field” refers to an electric field, a magnetic field, shear force, etc. For example, the resulting polymer electrolyte composite film is subjected to heat treatment, during which the external field such as an electric field, a magnetic field or shear force may be applied, whereby hydrophilic domains exhibiting ion conductivity can be oriented in the axial direction. There is a case where an oriented structure is obtained by designing the solvent for membrane production. In such a case, needless to say, it is unnecessary to apply the external field.

In the case where the method (2) is employed, specifically, the block copolymer is dissolved in an organic solvent to prepare a solution, and thereafter the solution is applied onto the surface of a substrate by coating or the like, followed by evaporation of the solvent to produce a membrane. Here, coating means such as spin coating, dipping, roll coating, spraying or casting may be used as a method for coating the substrate surface. There are no particular limitations on the organic solvent (for preparing a polymer solution) used in producing the membrane, as long as the block copolymer can uniformly be dissolved therein and the microphase separation structure is obtainable.

Further, the membrane thus obtained is immersed in a hydrophilic solvent such as water or alcohol in which the solid acid has been dissolved, thus the solid acid can be introduced into hydrophilic domains of the block copolymer. When the method (2) is employed, though unable to introduce the solid acid in a large quantity as compared with the method (1), there is such an advantage that an excess solid acid can be prevented from precipitating in the electrolyte membrane because only the solid acid having been dissolved is introduced into hydrophilic domains.

A membrane-electrode assembly and a fuel cell which have the polymer electrolyte composite film according to the present invention are described below.

The above polymer electrolyte composite film of the present invention may be provided with electrodes to produce the membrane-electrode assembly that is an embodiment of the present invention. This membrane-electrode assembly is made up of the polymer electrolyte composite film of the present invention and catalyst electrodes opposite to each other with this membrane interposed therebetween. The catalyst electrodes each have a structure in which a catalyst layer is formed on the surface of a gas diffusion layer. There are no particular limitations on how to produce the membrane-electrode assembly, and known techniques may be used.

The polymer electrolyte composite film (or the membrane-electrode assembly) of the present invention may be used to produce a fuel cell by a known method. As an example of the constitution of the fuel cell, a constitution may be cited which is so made up as to have the above membrane-electrode assembly, a pair of separators with the membrane-electrode assembly interposed therebetween, and collecting electrodes and packings which are attached to the separators. The separator on the anode side is provided with an anode-side opening, through which hydrogen gas or a gas fuel or liquid fuel of alcohols such as methanol is fed. The separator on the cathode side is provided with a cathode-side opening, through which oxygen gas or an oxidizer gas such as air is fed. Gas flow channels such as foamed metals may be provided in place of the separators or between the separators and the gas diffusion layers.

When a fuel cell is produced by the use of the polymer electrolyte composite film described above, good start-up performance is brought about even under low relative humidity conditions, e.g., at the time of starting the fuel cell.

### EXAMPLES

The present invention is described below in greater detail by way of working examples. The present invention is by no means limited thereto.

First, polymers of various types were synthesized by the following procedures.

### Synthesis Example 1

### Synthesis of Block Copolymer (BP-2) Composed of Carboxylic-Acid-Containing Block and Polystyrene Block

In an atmosphere of nitrogen, 0.6 millimoles of copper(I) bromide, 0.6 millimoles of 1,1,4,7,10,10-hexamethyltriethylenetetramine, 0.4 millimoles of methyl 2-bromopropionate and 50 millimoles of tert-butyl acrylate (tBA) were mixed, and then dissolved oxygen was displaced with nitrogen. Thereafter, reaction was carried out at 70° C. The reaction was performed while the rate of polymerization was ascertained by gas chromatography (GPC), and the reaction was quenched with liquid nitrogen. The molecular weight of poly-tBA obtained was ascertained by GPC to result in Mn=10,600 and Mw/Mn=1.07.

Next, 0.4 millimoles of the resulting poly-tBA having bromine at the terminal, 0.4 millimoles of copper(I) bromide, 0.4 millimoles of hexamethyltriethylenetetramine and 800 millimoles of styrene were mixed, followed by displacement with nitrogen. Reaction was carried out at 100° C., and thereafter was quenched with liquid nitrogen. After purification by reprecipitation into methanol, the molecular weight of PtBA-b-PSt (BP-1) obtained was ascertained by GPC to result in Mn=37,000 and Mw/Mn=1.18. From this result, the molecular weight of each block was calculated to be 10,600 for the PtBa block and 26,400 for the PSt block, showing good agreement with the compositional ratio of both the blocks which was found from the ratio of peak integration values of ¹H-NMR.

Next, the block copolymer BP-1 obtained was mixed with trifluoroacetic acid (5 equivalent weight based on the tert-butyl group) at room temperature in chloroform, and deprotection reaction was carried out to eliminate the tert-butyl group of the PtBA segment to convert it into a carboxylic acid, thereby obtaining polyacrylic acid-b-polystyrene (PAA-b-PSt) (BP-2). The volume fraction of the carboxylic-acid-containing block in BP-2 was 19%.

### Synthesis Example 2

### Synthesis of Block Copolymer (BP-3) Composed of Sulfonic-Acid-Containing Block and Polystyrene Block

The block copolymer BP-2 obtained in Synthesis Example 1 was dissolved in tetrahydrofuran (THF). To the solution obtained, sodium hydride (10 equivalent weight based on the carboxylic acid) and 1,3-propanesultone (20 equivalent weight based on the carboxylic acid) were added, and heat reflux was carried out to effect sulfonation of the PAA segment, to thereby obtain the desired block copolymer (BP-1) represented by the structural formula (1), having the sulfonic acid group as an ion exchange group. The volume fraction of the sulfonic-acid-containing block in BP-3 was 25%. The structural formula of this block copolymer PB-3 is shown below.

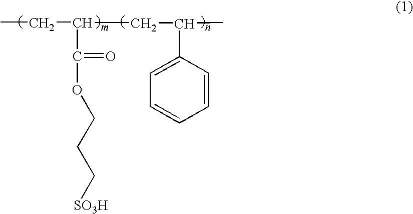

### Synthesis Example 3

### Synthesis of Carboxylic-Acid-Containing Random Copolymer (RP-2)

In an atmosphere of nitrogen, 0.13 millimoles of copper(I) bromide, 0.13 millimoles of 1,1,4,7,10,10-hexamethyltriethylenetetramine, 0.09 millimoles of 1-phenylethyl bromide, 40 millimoles of styrene monomer (St) and 10 millimoles of tert-butyl acrylate (tBA) were mixed, and then dissolved oxygen was displaced with nitrogen. Thereafter, reaction was carried out at 110° C. The reaction was performed while the rate of polymerization was ascertained by gas chromatography (GPC), and was quenched with liquid nitrogen. The molecular weight of PtBA-r-PSt (RP-1) obtained was ascertained by GPC to result in Mn=28,000 and Mw/Mn=1.99. The compositional ratio of St to tBA which was found from the ratio of peak integration values of ¹H-NMR was tBA/St=50/212.

Next, the random copolymer RP-1 obtained was mixed with trifluoroacetic acid (5 equivalent weight based on the tert-butyl group) at room temperature in chloroform, and deprotection reaction was carried out to eliminate the tert-butyl group of the PtBA segment to convert it into a carboxylic acid, thereby obtaining polyacrylic acid-r-polystyrene (PAA-a-PSt) (RP-2).

### Synthesis Example 4

### Synthesis of Sulfonic-Acid-Containing Random Copolymer (RP-3)

The random copolymer RP-2 obtained in Synthesis Example 3 was dissolved in THF. To the solution obtained, sodium hydride (10 equivalent weight based on the carboxylic acid) and 1,3-propanesultone (20 equivalent weight based on the carboxylic acid) were added, and heat reflux was carried out to effect sulfonation of the PAA segment, to thereby obtain a random copolymer (RP-3) having the sulfonic acid group as an ion exchange group.

### Example 1

The block copolymer BP-2 having the carboxylic acid group as an ion exchange group, obtained in Synthesis Example 1, and 10% by mass, 30% by mass or 60% by mass (based on BP-2) of phosphotungstic acid (PWA) were dissolved in a mixed solvent of THF:MeOH=7:3 so as to be in a solid content of 10% by mass, to prepare polymer solutions.

The polymer solutions thus prepared were dropped on glass substrates to produce three types of cast films different in PWA content. The cast films obtained were all 50 μm in thickness, and were colorless and transparent, and were excellent in flexibility. The membranes obtained were each folded in half to examine their mechanical strengths. As a result, it was ascertained that all the membranes did not break and had mechanical strength high enough to be used as electrolyte membranes of fuel cells.

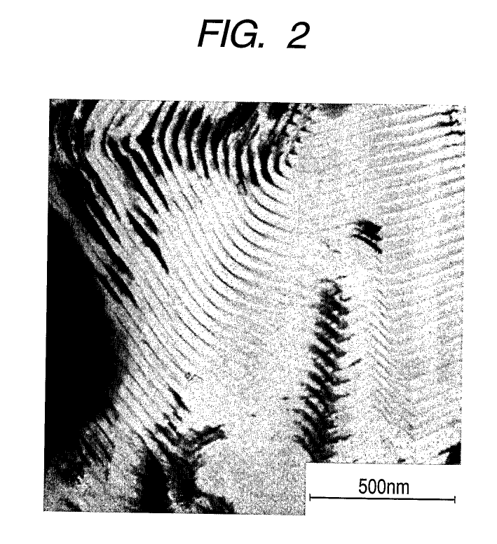

Cross-sections of these polymer membranes were observed with a transmission electron microscope (TEM). An example thereof is shown in FIG. 2. FIG. 2 is a sectional view of the polymer membrane in which the PWA was introduced in the amount of 30% by mass based on BP-2. Black portions in FIG. 2 are moieties into which the PWA was introduced. In FIG. 2, any large agglomerates of PWA are not observed, where the black moieties into which the PWA was introduced are much present in hydrophilic domains of the microphase separation structure formed from the block copolymer. From this fact, it is understood that the PWA is predominantly introduced into hydrophilic domains, in other words, the content of the PWA in the hydrophilic domain is larger than the content of the PWA in the hydrophobic domain. Also in the cast films different in the PWA content, it was likewise ascertained that any large agglomerates of PWA were not observed and the PWA was predominantly introduced into hydrophilic domains of the microphase separation structure formed from the block copolymer.

Subsequently, alternating current impedance measurement was made (applied voltage: 5 mV; frequency: from 1 Hz to 1 MHz) by a four-terminal method, and the proton conductivity of each electrolyte membrane in the membrane plane direction was calculated from the resistance value found. As a result, the electrolyte membranes showed a tendency for ion conductivity to be improved with an increase in the proportion of the PWA introduced. At the temperature of 50° C. and the relative humidity of 50%, the ion conductivity of the electrolyte membrane in which the PWA was introduced in the proportion of 60% by mass was 2.5×10⁻³ S·cm⁻¹.

### Example 2

The block copolymer BP-2 having the sulfonic acid group as an ion exchange group, obtained in Synthesis Example 2, and 10% by mass, 30% by mass or 60% by mass (based on BP-2) of phosphotungstic acid (PWA) were dissolved in a mixed solvent of THF:MeOH=7:3 so as to be in a solid content of 10% by mass, to prepare polymer solutions.

The polymer solutions thus prepared were dropped on glass substrates to produce three types of cast films different in PWA content. The cast films obtained were all 50 μm in thickness, and were colorless and transparent, and were excellent in flexibility. The membranes obtained were each folded in half to examine their mechanical strengths. As a result, it was ascertained that all the membranes did not break and had mechanical strength high enough to be used as electrolyte membranes of fuel cells.

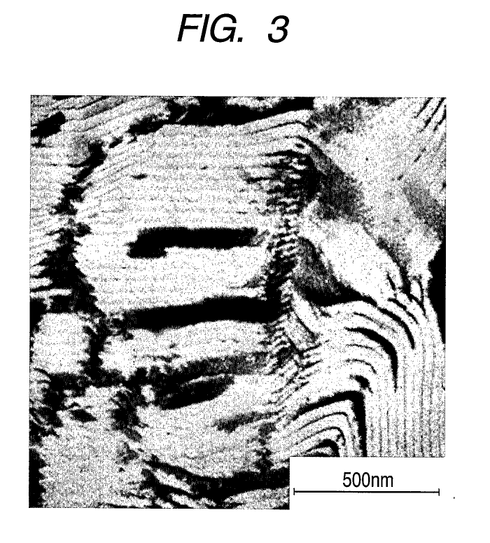

Cross-sections of these polymer membranes were observed with a transmission electron microscope (TEM). An example thereof is shown in FIG. 3. FIG. 3 is a sectional view of the polymer membrane in which the PWA was introduced in the amount of 30% by mass based on BP-2. It is understood from FIG. 3 that any large agglomerates of PWA are not observed and the PWA is predominantly introduced into hydrophilic domains of the microphase separation structure formed from the block copolymer. Also in the cast films different in PWA content, it was likewise ascertained that any large agglomerates of PWA were not observed and the PWA was predominantly introduced into hydrophilic domains of the microphase separation structure formed from the block copolymer.

Subsequently, alternating current impedance measurement was made by a four-terminal method, and the proton conductivity of each electrolyte membrane in the membrane plane direction was calculated from the resistance value found. As a result, the electrolyte membranes showed a tendency for ion conductivity to be improved with an increase in the proportion of the PWA introduced. At the temperature of 50° C. and the relative humidity of 50%, the ion conductivity of the electrolyte membrane in which the PWA was introduced in the proportion of 60% by mass was 2.6×10⁻² S·cm⁻¹.

### Comparative Example 1

The carboxylic-acid-containing random copolymer (RP-2) obtained in Synthesis Example 3, and 10% by mass, 30% by mass or 60% by mass (based on RP-2) of phosphotungstic acid (PWA) were dissolved in a mixed solvent of THF:MeOH=7:3 so as to be in a solid matter concentration of 10% by mass, to prepare polymer solutions.

The polymer solutions thus prepared were dropped on glass substrates to produce three types of cast films different in PWA content. The cast films obtained were all 50 μm in thickness, and were brittle in which white powder of PWA was deposited. The membranes obtained were each folded in half to examine their mechanical strengths. As a result, all the membranes were so hard and brittle as to break.

Since the membranes obtained were brittle, it was unable to measure the proton conductivity.

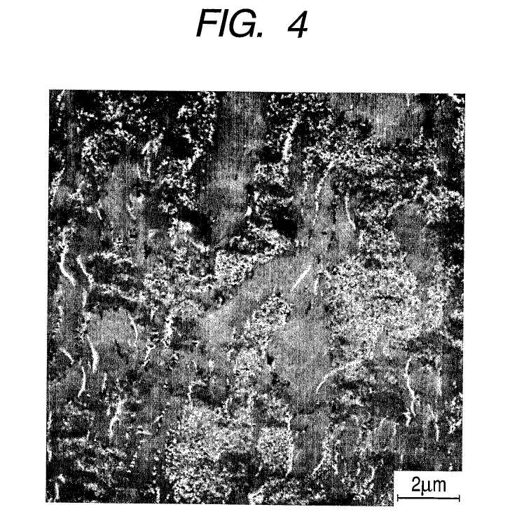

Cross-sections of these polymer membranes were observed with a transmission electron microscope (TEM). An example thereof is shown in FIG. 4. FIG. 4 is a sectional view of the polymer membrane in which the PWA was introduced in the amount of 30% by mass based on RP-2. As shown in FIG. 3, no microphase separation structure was observed because of the random copolymer, and agglomerates of 2 μm or more in size were observed in which the polymer and the PWA were macrophase-separated. Also in the cast films different in PWA content, it was likewise ascertained that any microphase separation structure was not observed and large agglomerates were seen.

### Comparative Example 2

The random copolymer (RP-3) having the sulfonic acid group as an ion exchange group, obtained in Synthesis Example 4, and 10% by mass, 30% by mass or 60% by mass (based on RP-3) of phosphotungstic acid (PWA) were dissolved in a mixed solvent of THF:MeOH=7:3 so as to be in a solid content of 10% by mass, to prepare polymer solutions.

The polymer solutions thus prepared were dropped on glass substrates to produce three types of cast films different in PWA content. The cast films obtained were all 50 μm in thickness, and were hard in which white powder was more deposited with an increase in the proportion of the PWA introduced. The membranes obtained were each folded in half to examine their mechanical strengths. As a result, all the membranes were so hard and brittle as to break.

Cross-sections of these polymer membranes were observed with a transmission electron microscope (TEM). As a result, as in Comparative Example 1, no microphase separation structure was not observed because of the random copolymer, and agglomerates of 2 μm or more in size were observed in which the high polymer and the PWA were macrophase-separated. Also in the cast films different in PWA content, it was likewise ascertained that any microphase separation structure was not observed and large agglomerates were seen.

Subsequently, alternating current impedance measurement was made by a four-terminal method, and the proton conductivity of each electrolyte membrane in the membrane plane direction was calculated from the resistance value found. As a result, at the temperature of 50° C. and the relative humidity of 50%, the ion conductivity of the electrolyte membrane in which the PWA was introduced in the proportion of 60% by mass was 6.9×10⁻³ S·cm⁻¹.

### Example 3

A membrane-electrode assembly and a fuel cell were produced.

HiSPEC1000 (registered trademark; available from Johnson Matthey) was used as a catalyst powder, and a NAFION (registered trademark) solution, available from DuPont), was used as an electrolyte solution. First, a mixture dispersion of the catalyst powder and electrolyte solution was prepared, and a film was formed from the dispersion on a PTFE sheet by means of doctor blade coating to produce a catalyst sheet. Next, using the decal method, the catalyst sheet produced was transferred at 150° C. and 100 kgf/cm² by hot pressing onto the polymer electrolyte composite film obtained in Example 1, to thereby produce the membrane-electrode assembly. Further, this membrane-electrode assembly was interposed between carbon cloth electrodes (E-TEK, available from BASF Fuel Cell, Inc.), and were held between collecting electrodes and joined together to produce the fuel cell.

Using the fuel cell thus produced, hydrogen gas was fed to the anode side at an injection rate of 300 ml/min, and air was fed to the cathode side, while setting the cell outlet pressure at the atmospheric pressure, the relative humidity at 50% on both the anode and the cathode, and the cell temperature at 50° C. Measurement of constant current was made at a current density of 400 mA/cm². As a result, the fuel cell exhibited stable potential (600 mV) immediately after starting the cell, showing good start-up performance.

### INDUSTRIAL APPLICABILITY

The polymer electrolyte composite film of the present invention containing the solid acid can be produced with superior membrane properties, and hence can be used in membrane-electrode assemblies and in fuel cells.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-131988, filed May 17, 2007, which is hereby incorporated by reference herein in its entirety.

1. A polymer electrolyte composite film, which contains a block copolymer comprising:
a hydrophilic block and a hydrophobic block; and
a solid acid,
wherein the polymer electrolyte composite film has a microphase separation structure comprising:
a hydrophilic domain formed from the hydrophilic block, and
a hydrophobic domain formed from the hydrophobic block, and
wherein the solid acid is localized in the hydrophilic domain.

2. The polymer electrolyte composite film according to claim 1, wherein the hydrophilic block comprises an ion conductive component and the hydrophobic block comprises an ion non-conductive component.

3. The polymer electrolyte composite film according to claim 1, wherein the microphase separation structure is a structure in which a continuous phase comprising the hydrophilic domain is present in a matrix comprising the hydrophobic domain.

4. The polymer electrolyte composite film according to claim 1, wherein the solid acid is a heteropolyacid.

5. A membrane-electrode assembly, which comprises the polymer electrolyte composite film according to claim 1.

6. A fuel cell, which comprises the polymer electrolyte composite film according to claim 1.

7. A process for producing a polymer electrolyte composite film, the process comprising the steps of:
applying to a substrate surface a solution, which contains a block copolymer comprising a hydrophilic block and a hydrophobic block, a solid acid, and a solvent; and
evaporating the solvent contained in the solution applied to the substrate surface.
